(19) United States
(12) Patent Application Publication
(10) Pub. No.: US 2013/0288489 A1
(43) Pub. Date: Oct. 31, 2013

(54) Method and Apparatus to Fabricate Vias in Substrates for Gallium Nitride MMICs

(71) Applicant: TransLith Systems, LLC, (US)

(72) Inventors: Paul Hoff, Bedford, NH (US); Donald Ronning, Nashua, NH (US)

(21) Appl. No.: 13/855,031

(22) Filed: Apr. 2, 2013

Related U.S. Application Data
(63) Continuation-in-part of application No. 12/800,554, filed on May 17, 2010.
(60) Provisional application No. 61/619,388, filed on Apr. 2, 2012.
(60) Provisional application No. 61/216,306, filed on May 15, 2009.

(51) Int. Cl. H01L 21/768

(52) U.S. Cl. CPC H01L 21/76825
USPC 438/798; 219/121.67

(57) ABSTRACT

A system for fabricating vias in SiC and CVD diamond substrates through controlled laser ablation using short pulse lengths and short wavelengths.

### CROSS-REFERENCE TO RELATED APPLICATIONS

The present application claims the benefit of U.S. Provisional Patent Application No. 61/619,388 filed on Apr. 2, 2012, and is a continuation-in-part of U.S. patent application Ser. No. 12/800,554 filed on May 17, 2010, which claims the benefit of U.S. Provisional Patent Application No. 61/216,306 filed on May 15, 2009, all of which are incorporated herein by reference.

### TECHNICAL FIELD OF THE INVENTION

The present invention relates to a method and apparatus to fabricate vias in the substrate for a gallium nitride monolithic microwave integrated circuit (“MMIC”). More specifically, it relates to a method and apparatus to create vias in the substrate for a gallium nitride MMIC through the use of controlled laser ablation.

### BACKGROUND OF THE INVENTION

A MMIC is a type of integrated circuit (“IC”) device that operates at microwave frequencies (300 MHz to 300 GHz). MMICs are typically small (from around 1 mm² to 10 mm²) and are amenable to mass production, which has allowed the proliferation of such high frequency devices. MMICs can he fabricated using gallium arsenide (“GaAs”), as it has fundamental advantages over silicon (“Si”), which is the traditional material used in IC manufacture. For example, GaAs provides better device (transistor) speed, which helps with the design of high frequency circuit functions. Gallium nitride (“GaN”) is also an option for MMICs. Because GaN transistors can operate at much higher temperatures and work at much higher voltages than GaAs transistors, they make ideal power amplifiers at microwave frequencies.

A via, or vertical interconnect access, is a vertical electrical connection between different layers of conductors in a physical electronic circuit. Vias enable the construction of high frequency, high power MMICs, by providing a low inductance path from the device to the ground plane of the circuit. High power MMIC designs commonly utilize backside vias that are fabricated through a GaAs substrate for GaAs circuits, and through a silicon carbide (“SiC”) substrate in the case of GaN circuits, where GaN is a high band gap material and SiC is a good thermal conductive material. Currently there is great difficulty in fabricating vias in SiC substrates of GaN MMICs. Typically, a simplified deep reactive-ion etching (“DRIE”) process is used that is very time consuming and has difficulty in producing and controlling multiple high aspect ratio structures.

MMICs generate a large amount of heat within the circuit structure on the GaN. The heat is removed partly by the vias, which are metal filled, but is removed primarily by thermal conduction through the substrate. The thermal conductivity of chemical vapor deposition (“CVD”) diamond is higher than SiC, which is higher than GaAs. The thermal loading and power output of GaN MMICs on CVD diamond and SiC are higher than GaAs.

Thus, there are several benefits for using a CVD diamond substrate for a GaN circuit, including improved, thermal conductivity. However, there is no known commercial method of fabricating vias in CVD diamond substrates of GaN MMICs.

The present invention is a method and apparatus to use controlled laser ablation of substrate materials to fabricate vias. Current technologies for laser ablation of materials use either long pulses at short wavelength or short pulses at long wavelength. Both technologies have significant short comings as described in U.S. patent application Ser. No. 12/800,554. It is, therefore, desirable to ablate materials using lasers that have a short pulse length at a short wavelength. Such lasers remove material without undue heating or damage to the surrounding areas and have the depth control desired.

it is a goal of the present invention to achieve controlled laser ablation through the use of short pulse lengths and short wavelengths and lowering the threshold intensity required for ablation in materials such as SiC and CVD diamond.

### SUMMARY

The present invention is a method and apparatus for the fabrication of vias in SiC and CVD diamond through the controlled laser ablation of the SiC and CVD diamond. It involves the use of lasers that have a short pulse length at a short wavelength to ablate material without undue heating or damage to the surrounding areas and with desired depth control.

These aspects of the invention are not meant to be exclusive and other features, aspects, and advantages of the present invention will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic diagram of a via;

FIG. 2 is a schematic diagram of a preferred embodiment of the present invention;

FIG. 3 is a drawing of the band gap structure of SiC;

FIG. 4 is a plot of the absorption coefficient versus the photon energy of photons in SiC;

FIG. 5 is a drawing of the band gap structure of diamond;

FIG. 6 is a plot of the absorption coefficient versus the photon energy of photons in CVD diamond;

FIG. 7 is a plot of the thermal conductivity of CVD diamond;

FIG. 8 is a plot of the thermal conductivity of SiC; and

FIG. 9 is a schematic diagram of the compaction of a MMIC structure with a CVD diamond substrate.

### DETAILED DESCRIPTION OF PREFERRED EMBODIMENTS

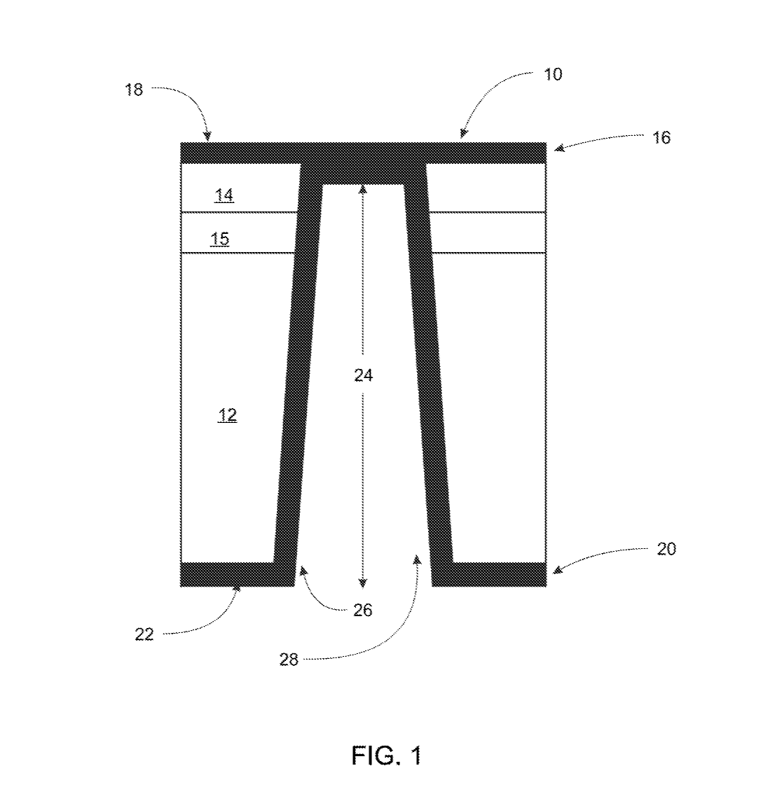

In FIG. 1, a section of a high power RF circuit or other semiconductor device 10 is shown to demonstrate a via. The high power RE circuit (MMIC) or other semiconductor device 10 includes a substrate 12 and a GaN material device region 14 formed over the substrate. As described further below, device structures are typically formed, at least in part, within GaN material region 14. Device 10 further includes a non-conducting layer 15 formed on substrate 12, for example, to facilitate the subsequent deposition of GaN material device region 14. A topside electrical contact 16 (on a topside 18 of the device) and a backside electrical contact 20 (on a backside 22 of the device) are provided for connection to an external power supply that powers the device. Backside contact 20 is deposited within a via 24 that extends from backside 22 of the device. Via 24 extends through non-conducting layer 15 and into a conducting region (e.g., device region 14) within device 10. As a result of the deposition of backside contact 20 within via 24, current can flow between the backside contact and topside contact 16 through device region 14 without being blocked by non-conducting layer 15. Thus, vertical conduction through device 10 between backside contact 20 and topside contact 16 may be achieved despite the presence of non-conducting layer 15.

As used herein, “non-conducting” refers to a layer that prevents current flow or limits current flow to negligible amounts in one or more directions. “Non-conducting” layers, for example, may be formed of non-electrical conductor materials, or may be formed of semiconductor materials which have a band sufficiently offset from the layer adjacent the “non-conducting” layer. A “non-conducting” layer may be conductive in and of itself, but may still be non-conducting (e.g, in a vertical direction) as a result of a band offset or discontinuity with an adjacent layer. As used herein, “vertical conduction” refers to electrical current flow in a vertical direction within a device. “Vertical conduction” may be between backside contact and topside contact or may be between different layers within the device that are separated vertically.

It should be understood that when a layer is referred to as being “on” or “over” another layer or substrate, it can be directly on the layer or substrate, or an intervening layer also may he present. A layer that is “directly on” another layer or substrate means that no intervening layer is present. It should also be understood that when a layer is referred to as being “on” or over another layer or substrate, it may cover the entire layer or substrate, or a portion of the layer or substrate. As shown in the figures, the term “topside” refers to the upper surface of the device and the term “backside” refers to the bottom surface of the device. Thus, the topside is opposite the backside of the device.

Previously, non-conducting layer 15 would be formed on substrate 12 prior to the deposition of GaN material device region 14, for example, to accomplish one or more of the following: reducing crack formation in GaN material device region 14 by lowering thermal stresses arising from differences between the thermal expansion rates of GaN material device region 14 and substrate 12; reducing defect formation in GaN material device region 14 by lowering lattice stresses arising from differences between the lattice constants of GaN material device region 14 and substrate 12; and, increasing conduction between substrate 12 and GaN material device region 14 by reducing differences between the band gaps of substrate 12 and GaN material device region 14. It should be understood that non-conducting layer 15 also may be formed between substrate 12 and GaN material device region for a variety of other reasons.

In FIG. 1, via 24 extends through non-conducting layer 15 so that vertical conduction can occur in device 10. Thus, at a minimum, via 24 has a length 26 sufficient to create a conducting vertical path between topside contact 16 and backside contact 20. Via 24, for example, may extend to a position within the GaN material device region 14 to form such a conducting path. In some cases, via 24 may extend to a source region or a drain region formed within device 10.

The exact shape and dimensions of via 24 depend upon the application. A typical cross-sectional area of a via has dimensions of less than 100 microns by about 100 microns, and as small as 30 microns by 30 micron at backside 22. It may be preferable for via 24 to be tapered inward, as shown, thus giving the via a cone shape. The inward taper can facilitate deposition of backside contact 20 on side walls 28 of via 24, if needed. In FIG. 1, device 10 includes a single via 24. Other embodiments may include more than one via.

As used herein, the phrase “electrical contact” or “contact” refers to any conducting structure on the semiconductor device that may be effectively contacted by a power source including electrodes, terminals, contact pads, contact areas, contact regions and the like. Backside contact 20 and topside contact 16 are formed of conducting materials including certain metals. Any suitable conducting material known in the art may be used. The composition of contacts 16, 20 may depend upon the type of contact. For example, contacts 16, 20 may contact n-type material or p-type material. Suitable metals for n-type contacts include titanium, nickel, aluminum, gold, copper, and alloys thereof. Suitable metals for p-type contacts include nickel, gold, and titanium, and alloys thereof.

In some embodiments, backside contact 20 may provide an effective attachment to a heat sink. In these embodiments, backside contact 20 removes thermal energy generated during the operation of the device. This may enable device 10 to operate under conditions which generate amounts of heat that would otherwise damage the device. In particular, high power RF circuits and laser diodes that operate at high current densities may utilize backside contact 20 as a heat sink. Backside contact 20 may be specifically designed to enhance thermal energy removal. For example, backside contact 20 may be composed of materials such as copper and gold, which are particularly effective at removing heat. Also, backside contact 20 and via 24 may be designed so that a large surface area is in contact with device region 14—for example, by including multiple vias and/or vias that extend significantly into device region 14.

GaN material device region 14 comprises at least one GaN material layer. In some cases, GaN material device region 14 includes only one GaN material layer. In other cases, GaN material device region 14 includes more than one epitaxial GaN material layer with varying dopant concentrations. The different layers can form different regions of the semiconductor structure. A GaN material region also may include one or more layers that do not have a GaN material composition such as oxide layers or metallic layers.

Presently, there is great difficulty in fabricating vias in RF microcircuits comprising GaN regions on SiC substrates. These devices are created on a 1-2 micron thick GaN layer on a 100 micron thick SiC substrate. A simplified DRIE process used to process vias on a 4 wafer lot of these devices requires a metal mask process to define the ˜30 micron via connection to the source pads of the device from the backside of the wafer. The metal mask process involves the following steps: via photo (photoresist coat, bake, exposure, develop), seed metal deposition, and lift-off (Ni plate, photoresist removal), via photo photoresist coat (bake, exposure, develop), electroless plating (Ni metal mask 6-8 micron thick), via etch using an inductively conductive plasma system (SiC and GaN layers), followed by metal mask removal. The entire process typically takes about 85 hours Which has at least 50 hours of touch labor. It is estimated that the process of the present invention would take less than 2 hours with an additional 2 hours of touch labor.

Additionally, problems associated with DRIE include complex processing sequences, long process cycle times, and difficulty in producing and controlling multiple high aspect ratio structures of varying geometries during fabrication. There are two main technologies for high-rate DRIE: cryogenic and Bosch, although the Bosch process is the only recognized production technique. While both the cryogenic and Bosch processes can fabricate vertical walls, they are often slightly tapered or “scalloped” (not smooth). Polysilicon or metal masks are needed in the fabrication process, and these require several additional photo and. deposition steps adding to production time and cost.

The Bosch process, also known as pulsed or time-multiplexed etching can create deep penetration, steep-side walled features. The Bosch process alternates repeatedly between a plasma etch mode and a deposition mode to achieve nearly vertical structures. These etch/deposit steps are repeated many times resulting in a large number of very small isotropic etch steps taking place only at the bottom of the etched pits. The overall slow etch rate, differential etch rate dependent upon aspect ratio of the feature, challenge to control sidewall taper angle, and the complexity of the multi-step process cause great difficulty in semiconductor fabrication. Increasing the number of chemical cycles results in smoother sidewalls but also increases the processing time required.

A cryo-Bosch process typically proceeds at electrode temperatures less than 140° K and relies upon a blocking layer of chemically deposited material together with the cryogenic temperatures to inhibit the attack of the sidewall and mask. The reduced etch rate is dependent upon a chemical reaction which is sensitive to the low temperature. Unfortunately, the process time becomes even longer than the standard Bosch process.

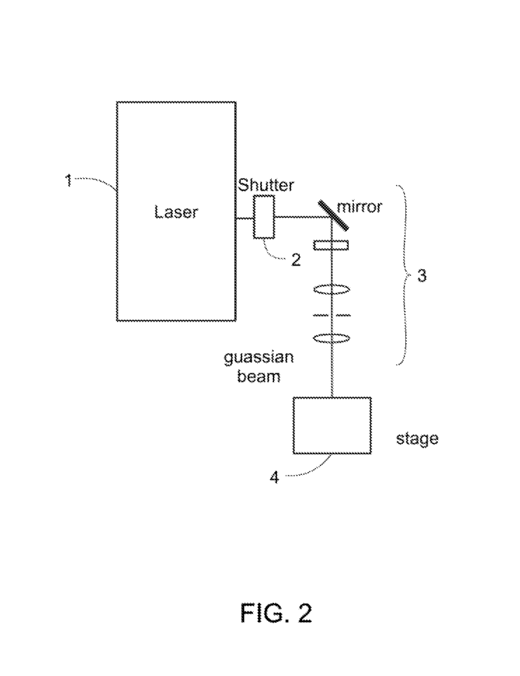

The present invention is a method and apparatus to utilize lasers with short pulse widths at short wavelengths to produce controlled ablation of material. It should be noted that the term laser as used herein includes frequency shifted laser systems. As shown in FIG. 2, a preferred embodiment of the present invention uses a frequency tripled. Yb:KYW (ytterbium ions in a lattice of potassium yttrium tungstate) laser 01 as the means for producing 100 fs pulses at a wavelength of 355 or 262 nm. It also includes a shutter 02 and an arrangement of one or more mirrors and lens 03, known to those skilled in the art, to focus a Gaussian beam or an appropriately structured beam on a stage 04. Also, other means known to those skilled in the art may be used to produce laser pulses with short pulse widths at short wavelengths.

The advantages of this embodiment are shown in machining SiC.

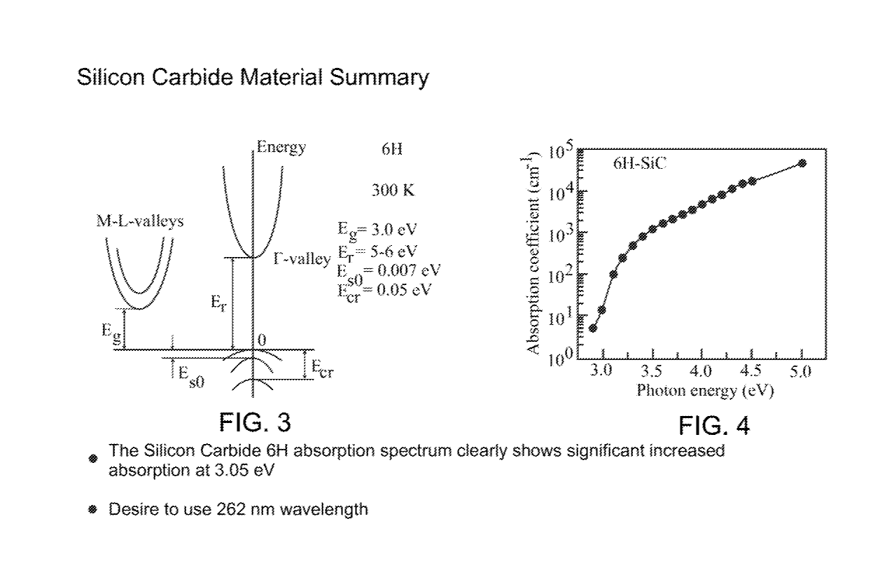

Below a wavelength of 305 nm silicon carbide has an indirect band gap absorption, as shown in FIG. 3. This absorption coefficient for single photon energy deposition increases by four orders of magnitude moving from a wavelength of 440 nm to one of 262 nm as shown in FIG. 4 which shows the onset of the indirect band gap absorption. At wavelengths of 262 nm electrons are excited from the valence band to a very high energy state in the conduction band within a 250 nm (2500A) absorption depth as shown in FIG. 4. These highly placed electrons can be photoionized (excited to a free ion state) by absorbing another photon (1 free electron for 2 photons) or can exchange energy with a valence band electron to end up with two lower energy conduction baud electrons, each of which can be photoionized in a single step (3 free electrons for 2 photons).

At intensities less than ˜10¹² W/cm² the excited electron density grows to the critical density for the 262 nm plasma frequency, nₑ˜1.6 10²²/cm⁻³. Absorption then proceeds by a classic free carrier absorption model, but the absorption depth is now determined by the material parameters. It is estimated that the main burst of energy will be absorbed in ˜150 nm with an energy absorption of 10-30 kJ/cm³. At this point, the energetic electrons leave the SiC and a Coulombic explosion follows. In other words, when electrons become energetic enough, they will leave the material surface leaving behind positively charged ions that then fly apart due to electrostatic forces. This creates a shock that blows away the material without any melting.

Another embodiment of the present invention is a method and apparatus for the fabrication of vias in CVD diamond substrates of Gall RF microcircuits. Currently, high performance power MMICs are fabricated in GaN on SiC substrates. While these devices offer improved performance over GaAs MMICs because of the higher thermal conductivity of SiC, they are still limited by the thermal transfer of the SiC. CVD diamond substrates offer a factor of three to five improvement in thermal conductivity over the SiC substrates. This would enable the field effect transistor (“FET”) periphery and area of the power MMICs to be reduced by a factor of three to five since the FETs could be driven harder. However, there is no known etch process for CVD diamond. DRIE shallow etching has been attempted on CVD diamond, but to achieve vias with high aspect ratio holes, the controlled ablation process of the present invention is needed. The laser ablation process of this embodiment of the present invention would enable the production of GaN MMICs on CVD diamond substrates with vias. The existing GaN MMICs on CVD diamond substrates are made without vias and are limited to operation at a few GHz. Using GaN MMICs on CVD diamond substrates with vias will enable the production of X band and W band MMICs. For X band systems the size reduction will allow increased power per element. The W band systems will have the advantage of increased power per element and reduced phase variation over the MMICs because of their reduced size.

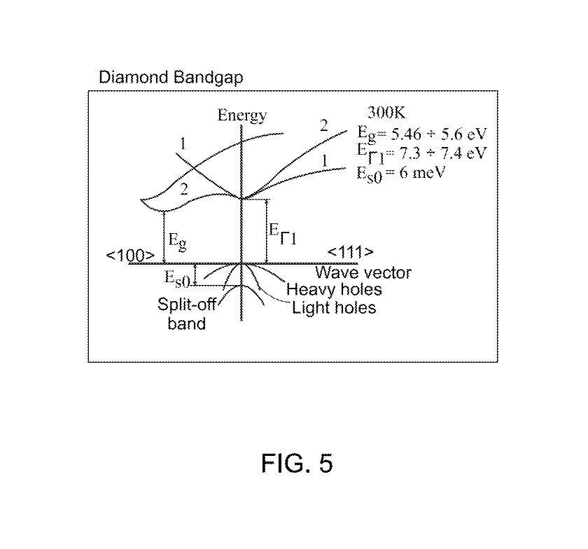

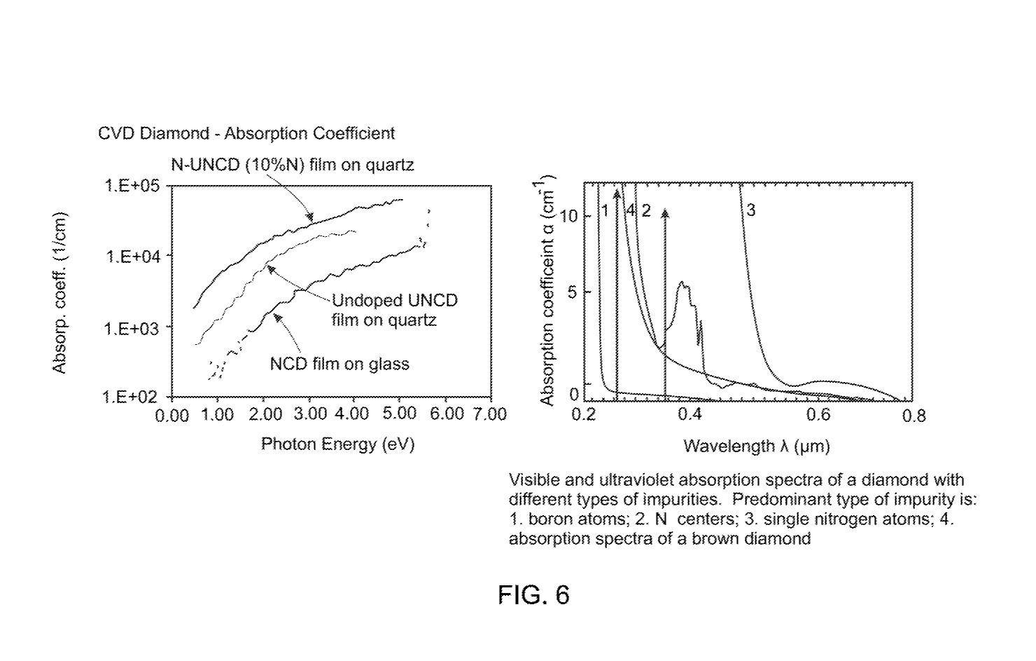

Diamond has a band gap optical absorption at 220 nm as shown in FIG. 5 whereas CVD diamond has an optical absorption that depends on the impurities present in the crystal as shown in FIG. 6. The impurities exist as a result of the growth process. In FIG. 6 it can he seen that at a wavelength of 262 nm that the CVD diamond is virtually opaque with impurities from N₃ centers or single nitrogen atoms. This means that the absorption depth is within a few molecular structures ˜10 nm.

At wavelengths of 262 nm electrons are excited from the valence band to a very high energy state in the conduction hand of this nitrogen impurity within a 10 nm (100A) absorption depth as shown in FIG. 6. These highly placed electrons can be photoionized (excited to a free ion state) by absorbing another photon (1 free electron for 2 photons) or can exchange energy with a valence band electron to end up with two lower energy conduction band electrons, each of which can be photoionized in a single step (3 free electrons for 2 photons).

At intensities less than ˜10¹¹ W/cm² the excited electron density grows to the critical density for the 262 nm plasma frequency, nₑ˜1.6 10²²/cm³. Up until this point, absorption proceeds on the nitrogen impurities. Now the absorption proceeds by a classic free carrier absorption model in a plasma of carbon and nitrogen, but the absorption depth is now determined by the material parameters. Although the initial free electrons are generated from the nitrogen impurity, the resulting plasma is comprised of the carbon and nitrogen impurities in the CVD diamond. It is estimated that the main burst of energy will be absorbed in ˜50 nm with an energy absorption of 10-30 kJ/cm³. At this point, the energetic electrons leave the CVD diamond and a Coulombic explosion follows. In other words, when electrons become energetic enough, they will leave the material surface leaving behind positively charged ions that then fly apart due to electrostatic forces. This creates a shock. that blows away the material without any melting. The impurities in this case act as an “ablation accelerant.”

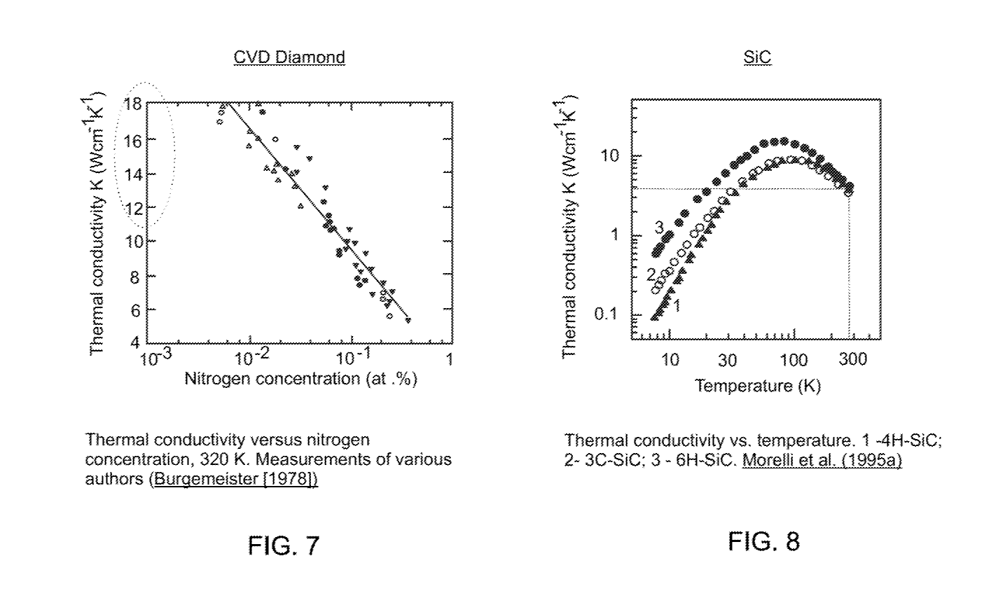

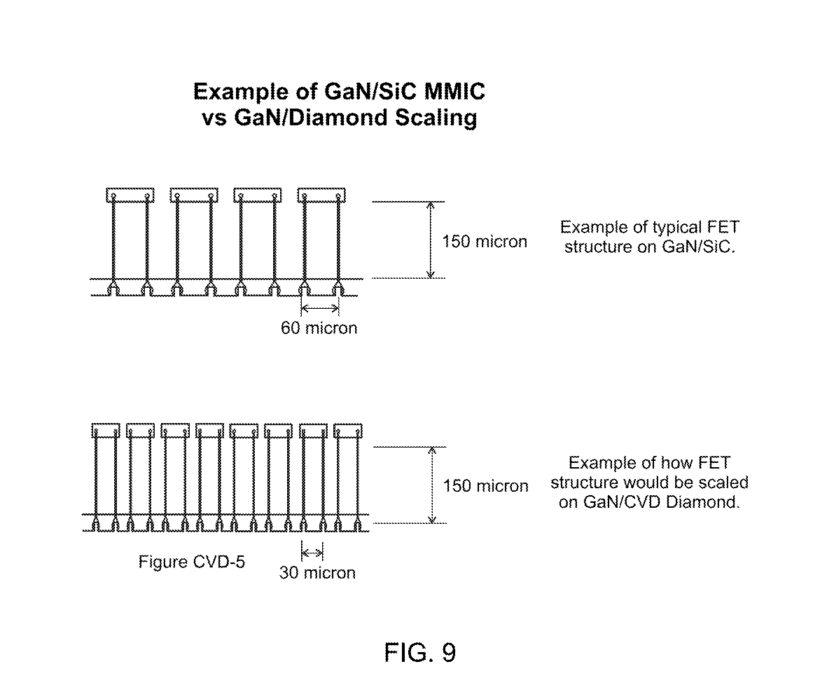

The thermal conductivity of CVD diamond is a factor three to live higher than SiC the other substrate material typically used for high power MMICs, as shown in FIG. 7 and FIG. 8. A 1% nitrogen impurity gives the increased thermal conductivity and is used to initiate the ablation process as discussed earlier. An example of the compaction of MMIC FET structure that can be achieved is shown in FIG. 9.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention.

What is claimed is:

1. An apparatus for fabricating vias in SiC through controlled laser ablation comprising,
a means to apply laser pulses in pulse widths of 500 fs or shorter at wavelengths of 360 nm or shorter to SiC; and
a lens to apply the laser pulses, wherein the intensity of each pulse is 10¹² W/cm² or less and each pulse produces a laser ablation depth of about 150 nm or less.

2. A method for fabricating vias in SIC through controlled laser ablation comprising,
applying a first photon to SiC to excite an electron to move from the valence hand to the conduction band;
applying a second photon to SiC to excite the electron from the conduction band to a free state, wherein the first and second photons are generated using a single laser pulse in pulse widths of 500 fs or shorter at wavelengths of 360 nm or shorter, wherein each of the laser pulses has an intensity of 10¹² W/cm² or less; and
producing a laser ablation depth of about 150 nm or less per laser pulse.

3. The method for controlled laser ablation of SiC of claim 2, further comprising the step of ablating an area with dimensions of less than 150 μm by about 150 μm.

4. An apparatus for fabricating vias in CVD diamond through controlled laser ablation comprising,
a means to apply laser pulses in pulse widths of 500 fs or shorter at wavelengths of 360 nm or shorter to CVD diamond; and
a lens to apply the laser pulses, wherein the intensity of each pulse is 10¹¹ W/cm² or less and each pulse produces a laser ablation depth of about 100 nm or less.

5. A method for fabricating vias in CVD diamond with an impurity through controlled laser ablation comprising,
applying a first photon to the CVD diamond with an impurity to excite an electron to move from the valence band to the conduction band of the impurity;
applying a second photon to CVD diamond to excite the electron from the conduction band of the impurity to a free state, wherein the first and second photons are generated using a single laser pulse in pulse widths of 500 fs or shorter at wavelengths of 360 nm or shorter, wherein each of the laser pulses has an intensity of 10¹¹ W/cm² or less; and
producing a laser ablation depth in the CVD diamond of about 100 nm or less per laser pulse.

6. The method for controlled laser ablation of CVD diamond of claim 5, further comprising the step of ablating an area with dimensions of less than 100 μm by about 100 μm.
